(19) United States
(12) Patent Application Publication
(10) Pub. No.: US 2025/0233509 A1
(43) Pub. Date: Jul. 17, 2025

(54) METHOD AND CONTROL CIRCUIT FOR OPERATING A HALF-BRIDGE CIRCUIT

(71) Applicant: Infineon Technologies Austria AG, Villach (AT)

(72) Inventors: Yi ZHANG, Shenzhen (CN); Cheng ZHANG, Shenzhen (CN); Sanbao SHI, Shenzhen (CN); Renhua XU, Shenzhen City (CN)

(21) Appl. No.: 19/013,033

(22) Filed: Jan. 8, 2025

(30) Foreign Application Priority Data
Jan. 15, 2024 (DE) 102024101032.0

(51) Int. Cl. H02M 1/088; H02M 1/00; H03K 17/687

(52) U.S. Cl. CPC H02M 1/088; H02M 1/0048; H03K 17/6872; H03K 17/6874

(57) ABSTRACT

A half-bridge includes a high-side switch and a low-side switch. A switching node is between the high-side switch and the low-side switch. A load is electrically connected to the switching node. In a first interval TP1 beginning with a current flow through the load in a first direction, the high-side switch is turned on for a first pulse time TL1 and the low-side switch is turned on for a first reverse conducting time TRC1 that begins after an end of the first pulse time TL1. In a second interval TP2 following the first interval TP1 and beginning with a current flow through the load in a second direction opposite the first direction, the low-side switch is turned on for a second pulse time TL2 and the high-side switch is turned on for a second reverse conducting time TRC2 starting after an end of the second pulse time TL2.

### CROSS-REFERENCE TO RELATED APPLICATION

This application claims priority to Germany Patent Application No. 102024101032.0 filed on Jan. 15, 2024, the content of which is incorporated by reference herein in its entirety.

### TECHNICAL FIELD

The present disclosure relates to a method for operating a half-bridge circuit and to a control circuit for controlling a half-bridge circuit.

### BACKGROUND

Half-bridge circuits each with a high-side switch and a low-side switch electrically connected in series between a positive DC supply voltage and a negative supply potential are used in power converting applications. A load is connected to a switching node between the high-side switch and the low-side switch. The high-side switch and the low-side switch alternately connect the switching node to the positive DC input voltage and the negative supply potential. A diode is effective in parallel with the high-side switch and another diode in parallel with the low-side switch, wherein both diodes block in a static operation of the half-bridge. The diode may be integral part of the switch or an additional device. For example, the diode may include the body diode of an MOSFET and/or an external anti-parallel diode (flyback diode).

When one of the high-side switch and the low-side switch is switched off, an inductive load connected to the switching node maintains a current flow through the inductive load and the diode electrically connected in parallel with the opposite switch.

The switching times for the high-side switch and the low-side switch and, as a result, the pulse time of a switched voltage at the switching node are controlled by pulse width modulation (PWM). By varying the duty cycle of the switch-on times of the high-side switch and the low-side switch, the PWM adapts the half-bridge operation to varying load conditions. For symmetric PWM, the duty ratio for the high-side switch and the low-side switch are identical. At least in some applications, symmetric PWM shows higher efficiency compared to complementary PWM.

There is an ongoing need for improving the operation of half-bridge circuits.

### SUMMARY

If the high-side switch and the low-side switch are metal-oxide semiconductor field effect transistors (MOSFETs), at least a part of a loop current maintained by the inductive load may flow through the body diode of one of the MOSFETs. If the MOSFET is a silicon carbide MOSFET (SIC-MOSFET), the forward voltage drop of the SiC-MOSFET body diode is higher than for a silicon MOSFET (Si-MOSFET) and affects efficiency of the half-bridge. In addition, the forward current through the SiC-MOSFET body diode is a bipolar current that can induce bipolar degradation of the silicon carbide crystal.

A method of operating a half-bridge that includes a high-side switch and a low-side switch includes: Turning on, in a first interval TP1 that begins with a current flow through a load electrically connected to a switching node between the high-side switch and the low-side switch in a first direction, the high-side switch for a first pulse time TL1 and the low-side switch for a first reverse conducting time TRC1, wherein the first reverse conducting time TRC1 starts after an end of the first pulse time TL1; and turning on, in a second interval TP2 that follows the first interval TP1 and begins with a current flow through the load in a second direction opposite the first direction, the low-side switch for a second pulse time TL2 and the high-side switch for a second reverse conducting time TRC2 starting after an end of the second pulse time TL2.

When one of the high-side switch and the low-side switch is switched off, an inductive load connected to the switching node maintains a current flow through the inductive load and the body diode of the opposite switch.

By contrast, the method according to the present disclosure provides an alternative current path through the closed MOS channel of the opposite switch. The current through the alternative current path is a unipolar current. The alternative current paths may be provided in addition to the body diodes and/or the anti-parallel diodes, wherein the alternative current paths may relieve the diodes from current and relax the requirements for the body diodes and/or the anti-parallel diodes.

Those skilled in the art will recognize additional features and advantages by reading the following detailed description and viewing the accompanying drawings.

### BRIEF DESCRIPTION OF THE DRAWINGS

The accompanying drawings are provided for further understanding of the implementations and form an integral part of this description. The drawings illustrate implementations of a method for operating a half-bridge circuit and a control circuit for operating a half-bridge circuit and, together with the description, explain the principles underlying the implementations. Further implementations are described in the following detailed description and in the claims. Features of the various implementations may be combined with each other.

FIG. 1A is a simplified circuit diagram of a half-bridge circuit for discussing effects of an operating method according to an implementation.

FIG. 1B is a simplified time chart for discussing effects of the operating method for the half-bridge of FIG. 1A according to an implementation.

FIGS. 2A and 2B are simplified circuit diagrams of a full bridge circuit including two half-bridge circuits for discussing effects of an operating method according to an implementation.

FIG. 3A is a simplified circuit diagram of a circuit including a full-bridge circuit and a control circuit for an operating method according to an implementation.

FIG. 3B is a simplified time chart for discussing effects of the operating method for the circuit of FIG. 3A according to an implementation.

FIG. 4 is a simplified circuit diagram of a circuit including a full-bridge circuit and a control circuit for an operating method according to an implementation concerning a low-current detection for controlling the reverse conducting times.

### DETAILED DESCRIPTION

In the following detailed description, reference is made to the accompanying drawings which form a part of this document and in which certain implementations of a method for operating a half-bridge circuit and a control circuit for operating a half-bridge circuit are shown as illustrations. Structural or logical changes may be made to the illustrated implementations without departing from the scope of the present disclosure. For example, features shown or described for one implementation may be used on or in conjunction with other implementations, resulting in another implementation. The present disclosure is intended to include such modifications and variations. The implementations are described in a manner that should not be construed as limiting the scope of the appended claims. The drawings are not to scale and are for illustrative purposes only. Corresponding elements are designated by the same reference numerals in the various drawings, unless otherwise indicated.

The terms “having”, “containing”, “including”, “comprising” and the like are open-ended, and the terms indicate the presence of certain structures, elements or features but do not preclude the presence of additional elements or features. The articles “a”, “an” and “the” include both the plural and singular, unless the context clearly indicates otherwise.

MOSFETs (metal oxide semiconductor field effect transistor) are voltage-controlled devices and include all types of IGFETs (insulated gate field effect transistors) with gate electrodes based on doped semiconductor material and/or metal and with gate dielectrics made of oxide and/or dielectric materials other than oxides.

Ranges given for physical dimensions include the boundary values. For example, a range for a parameter y from a to b reads as a≤y≤b. The same holds for ranges with one boundary value like “at most” and “at least”.

An implementation of the present disclosure concerns a method of operating a half-bridge that includes a high-side switch and a low-side switch. The high-side switch and the low-side switch may be electrically connected in series between a positive supply potential VDD and a negative supply potential VSS.

The high-side switch and the low-side switch may include the same type of semiconductor switch. For example, the high-side switch and the low-side switch are or include insulated gate bipolar transistors (IGBTs) with the same or approximately the same switching times, breakdown voltages and current-carrying capacities. Alternatively, the high-side switch and the low-side switch are or include MOSFETs with the same or approximately the same switching times, breakdown voltages and current-carrying capacities.

In a first interval TP1 that begins with a current flow through a load electrically connected to a switching node between the high-side switch and the low-side switch in a first direction, the high-side switch is turned on for a first pulse time TL1 and the low-side switch is turned on for a first reverse conducting time TRC1 starting after an end of the first pulse time TL1.

The first reverse conducting time TRC1 may follow the first pulse time TL1 directly or after a first dead time, wherein between the end of the first pulse time TL1 and the beginning of the first reverse conducting time TRC1 a body diode of the low-side switch and/or an anti-parallel diode electrically connected in parallel with the body diode of the low-side switch conducts the load current through the load that is connected to the switching node.

In a second interval TP2 following the first interval TP1 and starting with a current flow through the load in a second direction opposite to the first direction, the low-side switch is turned on for a second pulse time TL2 and the high-side switch is turned on for a second reverse conducting time TRC2 starting after an end of the second pulse time TL2.

The second reverse conducting time TRC2 may follow the second pulse time TL2 directly or after a second dead time, wherein between the end of the second pulse time TL2 and the beginning of the second reverse conducting time TRC2 a body diode of the high-side switch and/or an anti-parallel diode electrically connected in parallel with the body diode of the high-side switch conducts the load current.

The first intervals TP1 and the second intervals TP2 may have the same length, wherein the first intervals TP1 and the second intervals TP2 alternate. Every second interval TP2 may directly follow a preceding first interval TP1 and every first interval TP1 may directly follow a preceding second interval TP2.

The first reverse conducting time TRC1 may end within the first interval TP1 or with the beginning of the next second pulse time TL2. The second reverse conducting time TRC2 may end within the second interval TP2 or with the beginning of the next first pulse time TL1.

The second dead time and the first dead time may be equal or may differ from each other. Every first pulse time TL1 may directly follow a second reverse conducting time TRC2 or may follow the preceding second reverse conducting time TRC2 after a first idle time. Every second pulse time TL2 may directly follow a first reverse conducting time TRC1 or may follow the preceding first reverse conducting time TRC1 after a second idle time. The first and second idle times may be equal or may be different.

The first and second idle times may be phases without current or with only negligibly low current through the load. At any given time, at most one of the switches (high-side switch or low-side switch) is switched on.

The time interval between the beginning of two successive first pulse times and the time interval between the beginning of two successive second pulse times may be equal and define a total switching period of the half-bridge.

A total time of the first pulse time TL1 and the first reverse conducting time TRC1 and a total time of the second pulse time TL2 and the second reverse conducting time TRC2 are at most 50% of the switching period. The total time of the first pulse time TL1 and the first reverse conducting time TRC1 and the total time of the second pulse time TL2 and the second reverse conducting time TRC2 can be 50% or close to 50% of the switching period at heavy load and if the first and second dead times can be ignored. The total time of the first pulse time TL1 and the first reverse conducting time TRC1 and the total time of the second pulse time TL2 and the second reverse conducting time TRC2 can be less than 50% of the switching period at low load and/or if the first and second dead times are not negligible.

In the first intervals TP1, the high-side switch is turned on for a first pulse time TL1 once or at least two times, depending on the application. In the second intervals TP2, the low-side switch is turned on for second pulse times TL2 once or at least two times, depending on the application.

In the first pulse times TL1, the switching node between the high-side switch and the low-side switch may be connected via the closed high-side switch to the positive supply potential VDD and via the inductive load and a further low-side switch of a further half-bridge to the negative supply potential VSS. When the high-side switch and the further low-side switch turn off, the magnetic field of the inductive load maintains a current flow through the inductive load in a first direction, wherein the voltage at the switching node falls below the negative supply potential VSS. Typically, the body diode of the low-side switch and/or an anti-parallel diode parallel to the body diode of the low-side switch allow a current flow from the negative supply potential VSS to the switching node to maintain the current through the inductive load.

By contrast, the operation method according to the present disclosure provides an alternative current path through the closed MOS channel of the low-side switch, which is reverse-biased as long as a current flows through the body diode of the low-side switch and/or the parallel anti-parallel diode. The current through the alternative current path is a unipolar current. The alternative current path may be provided in addition to the body diode and/or the anti-parallel diode, wherein the alternative current path may relieve the thermal and/or current strain for the body diode and/or the anti-parallel diode.

In the second pulse times TL2, the switching node is connected via the closed low-side switch to the negative supply potential VSS and via the inductive load and a further high-side switch of the further half-bridge to the positive supply potential VDD. When the low-side switch and the further high-side switch turn off, the magnetic field of the inductive load maintains a current flow through the inductive load in a second direction opposite the first direction to the switching node, wherein the voltage at the switching node exceeds the positive supply potential VDD. Typically, a body diode of the high-side switch and/or an anti-parallel diode parallel to the body diode of the high-side switch allow a current flow from the switching node to the positive supply potential VDD to maintain the current through the inductive load.

By contrast, the operation method according to the present disclosure provides an alternative current path through the closed MOS channel of the high-side switch, which is reverse-biased as long as a current flows through the body diode of the high-side switch and/or the anti-parallel diode electrically connected in parallel to the high-side switch.

The anti-parallel diode may be an additional diode electrically connected parallel to the body diode of the assigned switch, wherein the body diode is between an n type drain region and p type body region of an n-channel MOSFET.

According to an implementation, the high-side switch may include a silicon carbide field effect transistor and/or the low-side switch may include a silicon carbide field effect transistor.

Silicon carbide field effect transistors are subject to bipolar degradation, e.g., a steady decrease in crystal quality and a steady degradation of device parameters like the on-state resistance RDSon with increasing bipolar current budget. By using the unipolar MOS channel current at least for a great portion of the anti-parallel period, bipolar degradation can be significantly slowed down.

According to an implementation, a length (duration) of the first pulse time TL1 and a length (duration) of the second pulse time TL2 may be controllable.

According to an implementation, the length of the first pulse time TL1 and a length of the second pulse time TL2 can be controlled according to load conditions.

For example, a first output of a pulse width modulator (PWM) circuit is connected to a gate of the high-side switch and a second output of the PWM circuit is connected to a gate of the low-side switch, and the PWM circuit controls the first and second pulse times TL1, TL2 of the high-side switch and the low-side switch according to a symmetric pulse time modulation method.

According to an implementation, a first dead time between the first pulse time TL1 and the first reverse conducting time TRC1 and/or a second dead time between the second pulse time TL2 and the second reverse conducting time TRC2 may be preset.

For example, a minimum duration of the first dead time and/or the second dead time is in a range from 50 ns to 1 μs, for example 50 ns. The first dead time and/or the second dead time may be fixed or may be controllable to adapt to specific applications. According to other implementations, the first dead time and the second dead time may be longer than 1 μs. The first dead time and the second dead time may be equal or may differ from each other.

The first dead time may begin with a trailing edge of an active high-side gate signal, which is active during the first pulse time TL1. The first dead time may end with the leading edge of an active low-side gate signal, which is active during the first reverse conducting time TRC1.

The second dead time may begin with a trailing edge of an active low-side gate signal, which is active during the second pulse time TL2. The second dead time may end with the leading edge of an active high-side gate signal, which is active during the second reverse conducting time TRC2.

The first and second dead times are selected depending on the electrical properties of the low-side switch and the high-side switch as well as the switching frequency.

IGBTs, for example, are known to carry a considerable tail current after the gate voltage changes from active to inactive. Therefore, the first and second dead time should be sufficiently long until the tail current decays or falls to a negligible value. For example, the first and second dead time should be 1 μs or longer to ensure that only one of the IGBTs is switched on at any time.

MOSFETs, on the other hand, are known for fast switching. This means that the first and second dead time can be significantly shorter than 1 μs without the risk of more than one of the MOSFETs being switched on at the same time.

In addition, the dead time shall not influence the operation of a system including the half-bridge. Thus, the first and second dead times may be selected to be at most 10% of the switching period of the low-side switch and the high-side switch. For example, for a switching frequency of 100 kHz and a switching period of 10 μs, the first and second dead times can be less than 1 μs.

According to an implementation the first reverse conducting time TRC1 and the second reverse conducting time TRC2 may be preset. For example, the first reverse conducting time TRC1 and the second reverse conducting time TRC2 are fixed and independent from application parameters, an operational state and/or a load condition of the half-bridge circuit.

According to another implementation, the first reverse conducting time TRC1 and the second reverse conducting time TRC2 can be adjustable. In particular, the first reverse conducting time TRC1 and the second reverse conducting time TRC2 are variable and can be adapted or can adapt to different application parameters. For example, the first reverse conducting time TRC1 and the second reverse conducting time TRC2 are a function of a resistance of a resistor and/or a capacitance of a capacitor, wherein the first reverse conducting time TRC1 and the second reverse conducting time TRC2 are programmable by selecting an appropriate resistor and/or capacitor. Another example is an auxiliary circuit that adjusts the first reverse conducting time TRC1 and the second reverse conducting time TRC2 in response to an application signal controlled, e.g., by user settings. Adjusting the first reverse conducting time TRC1 and the second reverse conducting time TRC2 may follow the following considerations:

The time T in which a load current through the load drops to zero is a function of the peak load current Imax, the inductance L of the load and the supply voltage U which is determined by the voltage difference between the positive supply voltage VDD and the negative supply potential VSS according to equation −1:

$$T = L * I max / U \qquad \#1$$

The first reverse conducting time TRC1 and the second reverse conducting time TRC2 can be selected equal to T or shorter than T by a safety margin ΔT. The higher the inductance L of the load, the higher the peak current Imax and the lower the supply voltage U, the longer first reverse conducting time TRC1 and the second reverse conducting time TRC2 can be.

In circuits with invariable inductance L, supply voltage U and peak current Imax, a suitable first reverse conducting time TRC1 and a suitable second reverse conducting time TRC2 can be selected by the application signal or by a suitable circuit element affecting the first reverse conducting time TRC1 and/or the second reverse conducting time TRC2. The first reverse conducting time TRC1 and/or the second reverse conducting time TRC2 may remain unchanged during operation.

If at least one of the inductance L, supply voltage U and peak current Imax is variable and changes during operation, the auxiliary circuit may adapt the first reverse conducting time TRC1 and/or the second reverse conducting time TRC2 accordingly on the fly. In addition, the safety margin ΔT may be adapted to circuit parameters and tolerances and/or current operational conditions. The first reverse conducting time TRC1 can be preset to different preset values and the second reverse conducting time TRC2 can be preset to different preset values, wherein the preset values depend on an operational state, a switching period and/or a load condition of the half-bridge circuit.

According to an implementation, the method may further include detecting a first notification state indicating a point in time prior to a beginning of a second interval TP2 and setting an end of the first reverse conducting time TRC1 in response to detecting the first notification state. A notification signal indicating a change to the first notification state triggers the low-side switch to switch off.

The first notification state can indicate any event that reliably takes place within the first interval TP1 and prior to the beginning of the second interval TP2. For example, the first notification state may be any internal state of a control circuit for the half-bridge prior to the beginning of the second interval TP2.

In addition, the method may further include detecting a second notification state indicating a point in time prior to a beginning of a first interval TP1 and setting an end of the second reverse conducting time TRC2 in response to detecting the second notification state. A notification signal indicating a change to the second notification state triggers the high-side switch to switch off.

The second notification state can indicate any event that reliably takes place within the second interval TP2 and prior to the beginning of the first interval TP1. For example, the second notification state may be any internal state of the control circuit for the half-bridge prior to the beginning of the first interval TP1.

The more the reverse conducting times TRC1, TRC2 cover the time span in which a loop current is maintained by the load, the less bipolar current flows through the high-side switch and low-side switch in total, and the greater may be the benefit of the method.

According to an implementation, detecting the notification state may include detecting a decrease of a current through the load to below a preset threshold in the first and second reverse conducting times TRC1, TRC2.

For example, the first notification state may be that after beginning of the first reverse conducting time TRC1 the amount of the load current falls below a first threshold.

The first threshold is set sufficiently high to prevent the end of the first interval TP1 from being missed due to the detection of current measurement noise. The first threshold may be greater than 0.5%, 1%, or 2% of the maximum load current in the first interval TP1. For example, for a maximum load current of 100 A, the first threshold may be at least 0.5 A, at least 1 A or at least 2 A to also account for an overall control delay including a current measurement delay, a filter delay, and a PWM signal delay from the controller to the high-side switch.

The first threshold is set sufficiently low to achieve a sufficiently positive effect. The first threshold can be a maximum of 10% of the maximum load current in the first interval TP1. For a maximum load current of 100 A, the first threshold can be 10 A, or less.

The second notification state may be that after beginning of the second reverse conducting time TRC2 the amount of the load current falls below a second threshold.

The first and second thresholds can have the same current amount but with opposite signs. For example, if the first threshold is 1 A, the second threshold can be −1 A.

The reverse conducting times TRC1, TRC2 can adapt to varying operation conditions and the MOSFET channels can be turned on over the whole time in which a loop current is maintained by the load.

According to an implementation, beginning and end of the first reverse conducting time TRC1 may be given by times when a rising voltage ramp exceeds a corresponding threshold voltage or when a falling voltage ramp falls below a corresponding threshold voltage, and/or beginning and end of the second reverse conducting time TRC2 are given by times when a rising voltage ramp exceeds a corresponding threshold voltage or when a falling voltage ramp falls below a corresponding threshold voltage.

The first and second reverse conducting times can be programmed and/or controlled by adapting the slope of the voltage ramp and/or by shifting the threshold voltages, by way of example.

Another implementation of the present disclosure concerns a control circuit for operating a half-bridge that includes a high-side switch and a low-side switch. The high-side switch and the low-side switch may be electrically connected in series between a positive supply potential VDD and a negative supply potential VSS.

In a first interval TP1 beginning with a current flow through a load electrically connected to a switching node between the high-side switch and the low-side switch in a first direction, the high-side switch is turned on for a first pulse time TL1 and the low-side switch is turned on for a first reverse conducting time TRC1 starting after an end of the first pulse time TL1.

In a second interval TP2 following the first interval TP1 and beginning with a current flow through the load in a second direction opposite the first direction, the low-side switch is turned on for a second pulse time TL2 and the high-side switch is turned on for a second reverse conducting time TRC2 starting after an end of the second pulse time TL2.

According to an implementation a length of the first pulse time TL1 and a length of the second pulse time TL2 may be controllable.

According to an implementation a length of the first pulse time TL1 and a length of the second pulse time TL2 may be controllable in response to changing load conditions.

According to an implementation a first dead time between the first pulse time TL1 and the first reverse conducting time TRC1 and/or a second dead time between the second pulse time TL2 and the second reverse conducting time TRC2 may be preset or may be adjustable or controllable.

The first reverse conducting time TRC1 and the second reverse conducting time TRC2 may be preset, wherein the first reverse conducting time TRC1 and the second reverse conducting time TRC2 are fixed and independent from application parameters, an operational state and/or a load condition of the half-bridge circuit.

According to an implementation, the first reverse conducting time TRC1 and the second reverse conducting time TRC2 can be adjustable. In particular, the first reverse conducting time TRC1 and the second reverse conducting time TRC2 are variable and can be adapted or can adapt to different application parameters.

According to an implementation, the control circuit may include a processing circuit configured to terminate the first reverse conducting time TRC1 in response to receiving information about a first notification state indicating a point in time before or at a beginning of a second interval TP2. Both the first reverse conducting time TRC1 and the second reverse conducting time TRC2 can be adjustable and controllable.

An electric circuit may include the half-bridge, the control circuit and a notifier circuit that detects the first notification state and transmits a notification signal containing information about the first notification state.

The processing circuit may further be configured to terminate the second reverse conducting time TRC2 in response to receiving information about a second notification state indicating a point in time before or at a beginning of a next first interval TP1. The notifier circuit may detect the second notification state and transmit a notification signal containing information about the second notification state.

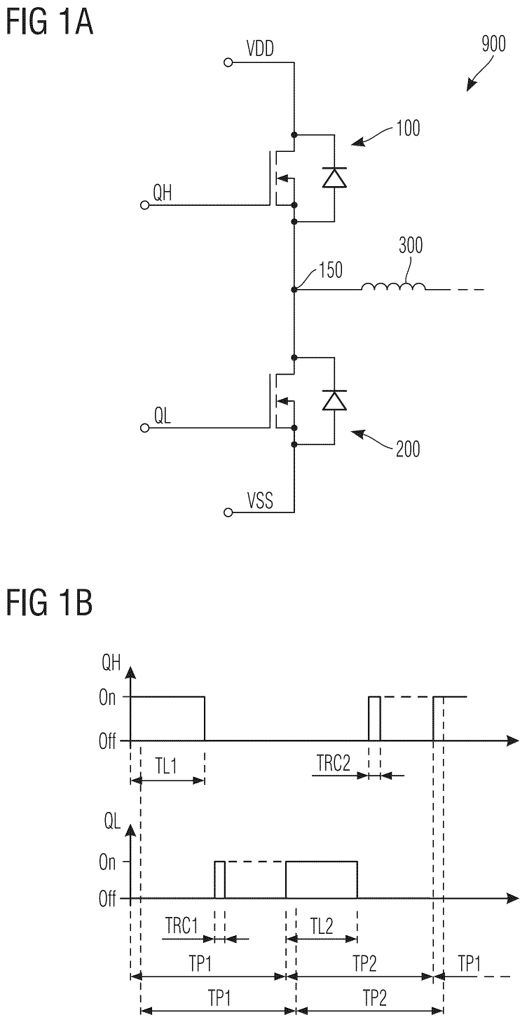

FIG. 1A shows a half-bridge circuit 900 with a high-side switch 100 and a low-side switch 200 electrically connected in series between a positive supply potential VDD and a negative supply potential VSS.

A first terminal of a load 300 with an inductive component is electrically connected to a switching node 150 between the high-side switch 100 and the low-side switch 200. The load 300 may include capacitive elements and resistive elements in addition to the inductive component but is configured such that the half-bridge circuit 900 operates in the inductive area.

A second terminal of the load 300 may be connected to the switching node of a further half-bridge circuit, by way of example.

The high-side switch 100 includes a first n channel SiC-MOSFET with an internal body diode 105 between an n doped drain region and a p doped base region that separates the n doped drain region and an n doped source region. The base region and the source region are electrically connected. A gate of the high-side switch 100 receives a high-side gate signal QH for controlling an MOSFET channel in the base region.

The low-side switch 200 includes a second n channel SiC-MOSFET with an internal body diode 205 between an n doped drain region and a p doped base region that separates the n doped drain region and an n doped source region. The base region and the source region are electrically connected. A gate of the low-side switch 200 receives a low-side gate signal QL for controlling an MOSFET channel in the base region.

FIG. 1B shows that the high-side and low-side gate signals QH, QL alternately turn on the high-side switch 100 and the low-side switch 200 such that none or only one of the high-side switch 100 and the low-side switch 200 is on at every point in time.

On times and off times of the high-side switch 100 and the low-side switch 200 are coordinated with first intervals TP1 and second intervals TP2. The solid lines illustrate the light load case. The dotted lines indicate the differences between the heavy load case and the light load case.

For light inductive loads, every first interval TP1 begins with a rising edge of the high-side gate signal QH turning on a load current from the positive supply potential VDD through the high-side switch 100 to the switching node 150 and passing through the load 300 in a first direction. Each first interval TP1 lasts until a load current begins to flow through the load 300 in the opposite second direction.

Every second interval TP2 begins with a rising edge of the low-side gate signal QL turning on a load current through the load 300, the switching node 150 and the low-side switch 200 to the negative supply voltage VSS. Each second interval TP2 lasts until a load current begins to flow through the load 300 in the first direction.

Intervals, in which no load current (I=0 A) or only a negligible load current flows through the load 300, separate intervals with opposite current directions.

For heavy inductive loads, the first reverse conducting time TRC1 and the second pulse time TL2 combine and merge directly into one signal pulse. Since the current lags behind the voltage due to operation in the inductive area, the current direction changes to the second direction only after the virtual rising edge of the second pulse time TL2 of the low-side gate signal QL within the merged signal pulse. Each second interval TP2 begins shortly after virtual rising edge of the second pulse time TL2 and lasts until the load current begins to flow through the load 300 in the opposite first direction.

Accordingly, the second reverse conducting time TRC2 and the first pulse time TL1 combine and merge directly into one signal pulse. Since the current lags behind the voltage, the current direction changes to the first direction only after the virtual rising edge of the first pulse time TL1 of the high-side gate signal QH. Each first interval TP1 begins shortly after virtual rising edge of the first pulse time TL1 and lasts until the load current begins to flow through the load 300 in the opposite second direction.

The current direction changes directly from the first direction to the second direction and vice versa. The length of the time lag depends on the characteristics of the load.

For light inductive loads, the high-side gate signal QH turns on the high-side switch 100 for a first pulse time TL1 at the beginning of each first interval TP1. For the complete first pulse time TL1, a load current flows from the positive supply potential VDD through the high-side switch 100 to the switching node 150 and passes the load 300 in the first direction. With a falling edge of the high-side gate signal QH, the load current through the high-side switch 100 is turned off. The magnetic field of the load 300 keeps a loop current flowing through the load 300 in the first direction for at least a part of the rest of the first interval TP1.

Still in the first interval TP1 and after turning off the high-side switch 100, the low-side gate signal QL becomes active and turns on the low-side switch 200 for a first reverse conducting time TRC1. For the first reverse conducting time TRC1, the loop current flows through the MOSFET channel of the low-side switch 200.

The first reverse conducting time TRC1 may follow the first pulse time TL1 directly or after a first dead time, wherein between the end of the first pulse time TL1 and the beginning of the first reverse conducting time TRC1 the body diode 205 of the low-side switch 200 conducts the loop current flowing through the load 300 in the first direction.

Still for light inductive loads, the low-side gate signal QL turns on the low-side switch 200 for a second pulse time TL2 at the beginning of each second interval TP2. For the complete second pulse time TL2, a load current passing the load 300 in the second direction flows through the switching node 150 and the low-side switch 200 to the negative supply potential VSS. With a falling edge of the low-side gate signal QL, the load current through the low-side switch 200 is turned off. The magnetic field of the load 300 keeps a loop current flowing through the load 300 in the second direction for at least a part of the rest of the second interval TP2.

Still in the second interval TP2 and after turning off the low-side switch 200, the high-side gate signal QH becomes active and turns on the high-side switch 100 for a second reverse conducting time TRC2. For the second reverse conducting time TRC2, the loop current flows through the MOSFET channel of the high-side switch 100.

The second reverse conducting time TRC2 may follow the second pulse time TL2 directly or after a second dead time, wherein between the end of the second pulse time TL2 and the beginning of the second reverse conducting time TRC2 the body diode 105 of the high-side switch 100 conducts the loop current flowing through the load 300 in the second direction.

The dotted lines in FIG. 1B refer to an implementation with the second pulse time TL2 directly following the preceding first reverse conducting time TRC1 and with the first pulse time TL1 directly following the preceding second reverse conducting time TRC2.

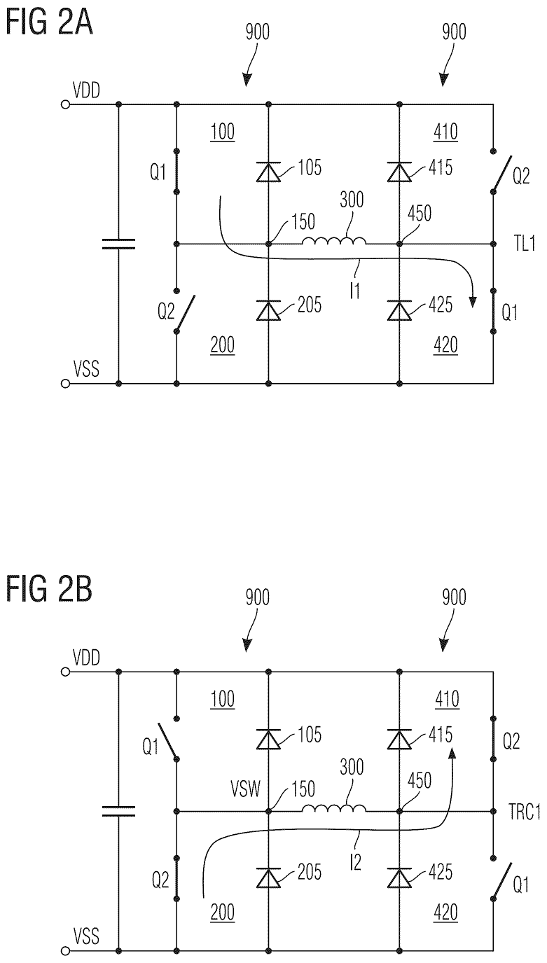

FIG. 2A and FIG. 2B refer to a full bridge including two half-bridges 900 as described with reference to FIG. 1A and FIG. 1B, wherein the load 300 is electrically connected between a first switching node 150 assigned to the first half-bridge 900 and a second switching node 450 assigned to the second half-bridge 900. A first gate signal Q1 provides the high-side gate signal for the first half-bridge 900 and the low-side gate signal for the second half-bridge 900. A second gate signal Q2 provides the high-side gate signal for the second half-bridge 900 and the low-side gate signal for the first half-bridge 900.

FIG. 2A illustrates the switching states and the current direction through the load 300 in the first pulse time TL1 of each first interval TP1. A load current I1 flows from the positive supply potential VDD through the high-side switch 100 of the first half-bridge 900, the load 300 and the low-side switch 420 of the second half-bridge 900 to the negative supply potential VSS. When the high-side switch 100 of the first half-bridge 900 and the low-side switch 420 of the second half-bridge turn off, the magnetic field of the load 300 maintains a loop current through the load 300 in direction from the first switching node 150 to the second switching node 450, wherein the voltage at the first switching node 150 falls below the negative supply potential VSS and the voltage at the second switching node 450 exceeds the positive supply potential VDD. Typically, the body diode 205 of the low-side switch 200 of the first half-bridge 900 and the body diode 415 of the high-side switch 410 of the second half-bridge 900 let pass the loop current.

FIG. 2B illustrates the switching states and the current direction through the load 300 in the first reverse conduction times TRC1 of each first interval TP1 after turning on the low-side switch 200 of the first half-bridge 900 and the high-side switch 410 of the second half-bridge 900 in a time period when the magnetic field of the load 300 maintains the current flow through the load 300. The MOSFET channels of the low-side switch 200 of the first half-bridge 900 and the high-side switch 410 of the second half-bridge 900 provide an alternative current path. The current through the MOSFET channels is a unipolar current. Since the voltage drop across the MOSFET channels along the current direction is smaller than the forward voltage of the body diodes, the MOSFET channels conduct a greater portion of the loop current than the body diodes. Equivalent considerations apply to the second period TP2 with the second half of the switching period.

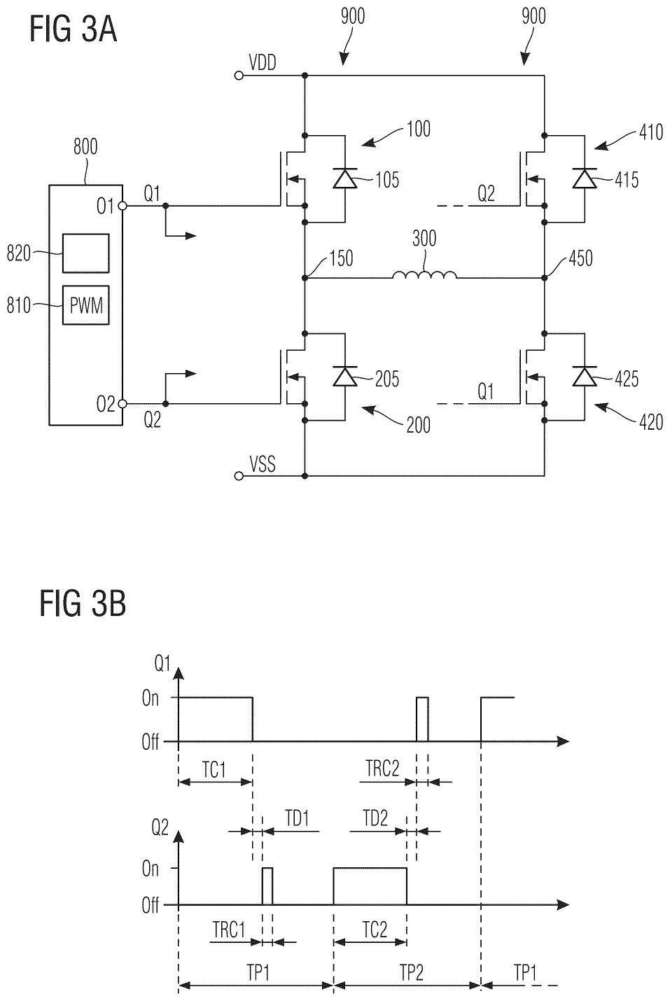

FIG. 3A shows an electronic circuit including the full-bridge with two half-bridges 900 as illustrated in FIG. 2A and a control circuit 800 that controls both half-bridges 900. The control circuit 800 generates and outputs the first gate signal Q1 controlling the high-side switch 100 of the first half-bridge 900 and the low-side switch 420 of the second half-bridge 900 and the second gate signal Q2 controlling the low-side switch 200 of the first half-bridge 900 and the high-side switch 410 of the second half-bridge 900.

FIG. 3B shows the first and second gate signals Q1, Q2 output by the control circuit 800.

The control circuit 800 includes a loop controller 810 such as a PWM circuit to control beginnings and ends of the first and second pulse times TL1, TL2, wherein the duration of the first and second pulse times TL1, TL2 may increase with increasing load. The loop controller 810 controls the first gate signal Q1 and the second gate signal Q2 according to a symmetric pulse time modulation method.

The control circuit 800 further includes a processing circuit 820 that controls beginning and end of the first and second reverse conducting times TRC1, TRC2. The first reverse conducting time TRC1 follows the first pulse time TL1 after a first dead time TD1. The second reverse conducting time TRC2 follows the second pulse time TL2 after a second dead time TD2. The first and second dead times TD1, TD2 are equal.

The processing circuit 820 may include a ramp generator circuit configured to output a rising or falling voltage ramp, and an auxiliary circuit configured to control at least beginning and end of the first reverse conducting time TRC1, and beginning and end of the second reverse conducting time TRC2 at times when the voltage ramp exceeds or falls below a corresponding threshold voltage. The amplitude of the voltage ramp may change linearly. The voltage ramp may linearly increase or may linearly decrease.

The start of the voltage ramp for controlling the first reverse conducting time TRC1 may be triggered by the start or the end of the first pulse time TL1. The start of the voltage ramp for controlling the second reverse conducting time TRC2 may be triggered by the start or the end of the second pulse time TL2.

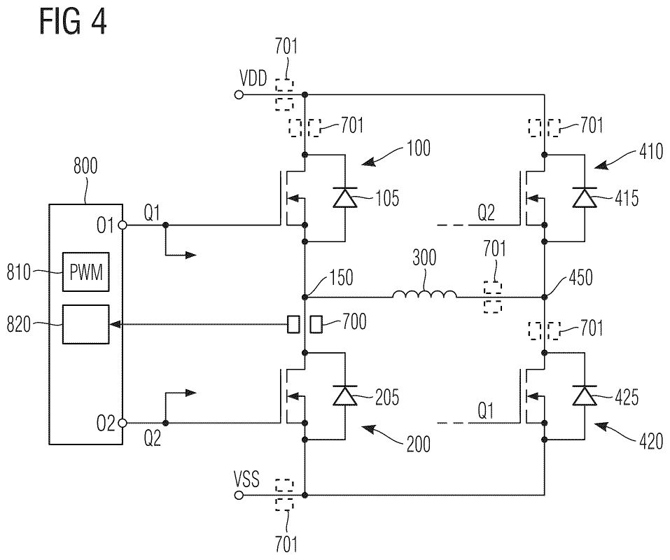

FIG. 4 shows an electronic circuit combining the full-bridge of FIG. 3A with a notifier circuit 700 for determining the end of the first and second reverse conducting times TRC1, TRC2, and a processing circuit 820 configured to receive a notification signal from the notifier circuit 700. The notification signal includes information about a notification state.

In the illustrated implementation, the notifier circuit 700 detects a current in one of the branches of the full-bridge and outputs a notification signal indicating a decrease of the amount of the current to below a preset threshold value in the first and second reverse conducting times TRC1, TRC2.

Reference signs 701 indicate alternative placements for the notifier circuit. Alternatively, the notifier circuit may include two or more sub-circuits placed in two or more different branches of the half-bridge, wherein the processing circuit 820 receives two or more notification signals and analyzes the received notification signals to determine the end of the first and second reverse conducting times TRC1, TRC2 based on information from more than one branch.

The processing circuit 820 receives the notification signal and controls the end of the first and second reverse conducting times TRC1, TRC2 in response to the information encoded in the notification signal. The notification signal may directly trigger the processing circuit 820 to switch off the low-side and high-side switches, respectively.

The notifier circuit 700 may include a sensing element for the current in the full-bridge, e.g., a shunt resistor or a Hall probe, and a comparator, by way of example.

Though discussed in detail with reference to a simplified full-bridge, the method also works in multi-phase topologies with symmetric pulse width modulation.

In resonant half-bridge converter that uses two inductors (LL) and a capacitor (C), known as LLC configuration, or two inductors (LL) and two capacitors (CC), known as CLLC configuration, the method of operating a half-bridge as discussed above reduces the conduction losses, in particular, when high-side switch and low-side switch are SiC-MOSFETs.

Further in a phase-shifted full bridge (PSFB) converter and a dual active bridge (DAB) converter, the method of operating a half-bridge as discussed above reduces the conduction losses, in particular, when high-side switch and low-side switch are SiC-MOSFETs.

### Aspects

The following provides an overview of some Aspects of the present disclosure:

Aspect 1: A method of operating a half-bridge that includes a high-side switch and a low-side switch, the method comprising: in a first interval, beginning with a current flow through a load electrically connected to a switching node between the high-side switch and the low-side switch in a first direction, turning on the high-side switch for a first pulse time and turning on the low-side switch for a first reverse conducting time starting after an end of the first pulse time; and in a second interval, following the first interval and beginning with a current flow through the load in a second direction opposite the first direction, turning on the low-side switch for a second pulse time and turning on the high-side switch for a second reverse conducting time starting after an end of the second pulse time.

Aspect 2: The method according to Aspect 1, wherein the high-side switch includes a silicon carbide field effect transistor and/or the low-side switch includes a silicon carbide field effect transistor.

Aspect 3: The method according to any of Aspects 1-2, wherein a length of the first pulse time and a length of the second pulse time are controllable.

Aspect 4: The method according to any of Aspects 1-3, wherein a length of the first pulse time and a length of the second pulse time are controlled according to one or more load conditions.

Aspect 5: The method according to any of Aspects 1-4, wherein at least one of a first dead time or a second dead time is present, wherein, when present, the first dead time is between the first pulse time and the first reverse conducting time is present, and wherein, when present, the second dead time is between the second pulse time and the second reverse conducting time.

Aspect 6: The method according to any of Aspects 1-5, wherein the first reverse conducting time and the second reverse conducting time are fixed.

Aspect 7: The method according to any of Aspects 1-6, wherein the first reverse conducting time and the second reverse conducting time are adjustable.

Aspect 8: The method according to any of Aspects 1-7, further comprising: detecting a first notification state indicating a point in time prior to a beginning of a second interval; and setting an end of the first reverse conducting time in response to detecting the first notification state.

Aspect 9: The method according to Aspect 8, wherein detecting the first notification state includes detecting a decrease of a current through the load to below a preset threshold in the first reverse conducting time and the second reverse conducting time.

Aspect 10: The method according to any of Aspects 1-9, wherein a beginning and an end of the first reverse conducting time are given by times when a rising voltage ramp exceeds a corresponding threshold voltage or when a falling voltage ramp falls below a corresponding threshold voltage, or wherein a beginning and an end of the second reverse conducting time are given by times when a rising voltage ramp exceeds a corresponding threshold voltage or when a falling voltage ramp falls below a corresponding threshold voltage.

Aspect 11: A control circuit for operating a half-bridge that includes a high-side switch and a low-side switch, the control circuit being configured to: in a first interval, beginning with a current flow through a load electrically connected to a switching node between the high-side switch and the low-side switch in a first direction, turning on the high-side switch for a first pulse time and turning on the low-side switch for a first reverse conducting time starting after an end of the first pulse time; and in a second interval, following the first interval and beginning with a current flow through the load in a second direction opposite the first direction, turning on the low-side switch for a second pulse time and turning on the high-side switch for a second reverse conducting time starting after an end of the second pulse time.

Aspect 12: The control circuit according to Aspect 11, wherein the control circuit is configured to adjust a length of the first pulse time and a length of the second pulse time.

Aspect 13: The control circuit according to any of Aspects 11-12, wherein the control circuit is configured to adjust a length of the first pulse time and a length of the second pulse time in response to one or more changing load conditions.

Aspect 14: The control circuit according to any of Aspects 11-13, wherein the control circuit is configured to provide a first dead time between the first pulse time and the first reverse conducting time, or wherein the control circuit is configured to provide a second dead time between the second pulse time and the second reverse conducting time.

Aspect 15: The control circuit according to any of Aspects 11-14, wherein the control circuit is configured to adjust the first reverse conducting time and the second reverse conducting time.

Aspect 16: The control circuit according to any of Aspects 11-15, further comprising: a processing circuit configured to terminate the first reverse conducting time in response to receiving information about a first notification state indicating a point in time before or at a beginning of a second interval.

Aspect 17: The control circuit according to any of Aspects 11-16, wherein the control circuit is configured to generate gate signals for controlling the high-side switch and the low-side switch, and wherein the control circuit comprises: a loop controller configured to control the first pulse time and the second pulse time; and a processing circuit configured to control the first reverse conducting time and the second reverse conducting time.

Aspect 18: The control circuit according to Aspect 17, wherein the loop controller is a pulse width modulation (PWM) circuit.

Aspect 19: A system configured to perform one or more operations recited in one or more of Aspects 1-18.

Aspect 20: An apparatus comprising means for performing one or more operations recited in one or more of Aspects 1-18.

1. A method of operating a half-bridge that includes a high-side switch and a low-side switch, the method comprising:
in a first interval, beginning with a current flow through a load electrically connected to a switching node between the high-side switch and the low-side switch in a first direction, turning on the high-side switch for a first pulse time and turning on the low-side switch for a first reverse conducting time starting after an end of the first pulse time; and
in a second interval, following the first interval and beginning with a current flow through the load in a second direction opposite the first direction, turning on the low-side switch for a second pulse time and turning on the high-side switch for a second reverse conducting time starting after an end of the second pulse time.

2. The method according to claim 1, wherein the high-side switch includes a silicon carbide field effect transistor and/or the low-side switch includes a silicon carbide field effect transistor.

3. The method according to claim 1, wherein a length of the first pulse time and a length of the second pulse time are controllable.

4. The method according to claim 1, wherein a length of the first pulse time and a length of the second pulse time are controlled according to one or more load conditions.

5. The method according to claim 1, wherein at least one of a first dead time or a second dead time is present,
wherein, when present, the first dead time is between the first pulse time and the first reverse conducting time is present, and
wherein, when present, the second dead time is between the second pulse time and the second reverse conducting time.

6. The method according to claim 1, wherein the first reverse conducting time and the second reverse conducting time are fixed.

7. The method according to claim 1, wherein the first reverse conducting time and the second reverse conducting time are adjustable.

8. The method according to claim 1, further comprising:
detecting a first notification state indicating a point in time prior to a beginning of a second interval; and
setting an end of the first reverse conducting time in response to detecting the first notification state.

9. The method according to claim 8, wherein detecting the first notification state includes detecting a decrease of a current through the load to below a preset threshold in the first reverse conducting time and the second reverse conducting time.

10. The method according to claim 1, wherein a beginning and an end of the first reverse conducting time are given by times when a rising voltage ramp exceeds a corresponding threshold voltage or when a falling voltage ramp falls below a corresponding threshold voltage, or
wherein a beginning and an end of the second reverse conducting time are given by times when a rising voltage ramp exceeds a corresponding threshold voltage or when a falling voltage ramp falls below a corresponding threshold voltage.

11. A control circuit for operating a half-bridge that includes a high-side switch and a low-side switch, the control circuit being configured to:
in a first interval, beginning with a current flow through a load electrically connected to a switching node between the high-side switch and the low-side switch in a first direction, turning on the high-side switch for a first pulse time and turning on the low-side switch for a first reverse conducting time starting after an end of the first pulse time; and
in a second interval, following the first interval and beginning with a current flow through the load in a second direction opposite the first direction, turning on the low-side switch for a second pulse time and turning on the high-side switch for a second reverse conducting time starting after an end of the second pulse time.

12. The control circuit according to claim 11, wherein the control circuit is configured to adjust a length of the first pulse time and a length of the second pulse time.

13. The control circuit according to claim 11, wherein the control circuit is configured to adjust a length of the first pulse time and a length of the second pulse time in response to one or more changing load conditions.

14. The control circuit according to claim 11, wherein the control circuit is configured to provide a first dead time between the first pulse time and the first reverse conducting time, or
wherein the control circuit is configured to provide a second dead time between the second pulse time and the second reverse conducting time.

15. The control circuit according to claim 11, wherein the control circuit is configured to adjust the first reverse conducting time and the second reverse conducting time.

16. The control circuit according to claim 11, further comprising:
a processing circuit configured to terminate the first reverse conducting time in response to receiving information about a first notification state indicating a point in time before or at a beginning of a second interval.

17. The control circuit according to claim 11, wherein the control circuit is configured to generate gate signals for controlling the high-side switch and the low-side switch, and
wherein the control circuit comprises:
a loop controller configured to control the first pulse time and the second pulse time; and
a processing circuit configured to control the first reverse conducting time and the second reverse conducting time.

18. The control circuit according to claim 17, wherein the loop controller is a pulse width modulation (PWM) circuit.
